(19) United States
(12) Patent Application Publication
(10) Pub. No.: US 2010/0060257 A1
(43) Pub. Date: Mar. 11, 2010

(54) CURRENT SENSOR FOR POWER CONVERSION

(76) Inventors: Firas Azrai, Austin, TX (US); Eric B. Smith, Austin, TX (US)

Correspondence Address: ZAGORIN O'BRIEN GRAHAM LLP, 7600B NORTH CAPITAL OF TEXAS HIGHWAY, SUITE 350, AUSTIN, TX, 78731, US

(21) Appl. No.: 12/551,011

(22) Filed: Aug. 31, 2009

Related U.S. Application Data
(60) Provisional application No. 61/094,750, filed on Sep. 5, 2008.

(51) Int. Cl. G01R 19/00

(52) U.S. Cl. 324/76.11

(57) ABSTRACT

A technique for determining an output current of a power converter circuit samples a voltage of a switch node voltage signal at a midpoint of a low phase of the switch node voltage signal and generates a sensed current signal at least partially based on the sampled switch node voltage and a calibration voltage. In at least one embodiment of the invention, an apparatus includes a current sensing circuit configured to generate a sensed current signal indicative of an average output current of a power converter circuit. The sensed current signal is at least partially based on a sample of a voltage signal on a first node of the power converter circuit. The first node is used to supply a current to an inductor of the power converter circuit.

### CROSS-REFERENCE TO RELATED APPLICATION(S)

This application claims the benefit of U.S. Provisional Application No. 61/094,750, filed Sep. 5, 2008, entitled “Integrated Multiple Output Power Conversion System,” and naming inventors Firas Azrai et al., which application is hereby incorporated by reference.

### BACKGROUND

1. Field of the Invention

This application relates to power conversion and more particularly to multi-output voltage converters.

2. Description of the Related Art

Modern integrated circuits can require multiple power rails. As levels of integration continue to increase, the number of power rails required on circuit boards is also increasing. This has led to multiple point of load regulators being placed on circuit boards relatively close to the device or devices requiring the particular rail. Single integrated circuits, such as microprocessors, can often require multiple power rails, e.g., one power rail for the processor core and a different power rail for the input/output (I/O) portion of the processor. As the number of power rails on the circuits boards proliferate, an ever increasing number of point of load regulators are being placed on circuit boards to accommodate the power needs of the system.

### SUMMARY

A technique for determining an output current of a power converter circuit samples a voltage of a switch node voltage signal at a midpoint of a low phase of the switch node voltage signal and generates a sensed current signal at least partially based on the sampled switch node voltage and a calibration voltage. In at least one embodiment of the invention, an apparatus includes a current sensing circuit configured to generate a sensed current signal indicative of an average output current of a power converter circuit. The sensed current signal is at least partially based on a sample of a voltage signal on a first node of the power converter circuit. The first node is used to supply a current to an inductor of the power converter circuit.

In at least one embodiment of the invention, a method includes determining an average output current of a power converter circuit at least partially based on a sample of a voltage signal on a first node of the power converter circuit. The first node is configured to supply a current to an inductor of the power converter circuit. The method may include sampling the voltage signal at a point when the current supplied to the inductor by the first node is approximately equal to the average output current of the power converter circuit. The method may include generating a sample clock signal having a transition at a midpoint of a first phase of the voltage signal. The sample clock signal is used to sample the voltage signal.

### BRIEF DESCRIPTION OF THE DRAWINGS

The present invention may be better understood, and its numerous objects, features, and advantages made apparent to those skilled in the art by referencing the accompanying drawings.

FIG. 1 is an exemplary functional block diagram of an embodiment showing a three output DC-to-DC converter.

FIG. 2 illustrates high-level architectural aspects of an embodiment of the invention.

FIG. 3 illustrates one aspect of shared control logic according to an embodiment of the invention.

FIG. 4 illustrates a block diagram of processing of the error signals.

FIG. 5 illustrates detail of a pulse-width modulator circuit according to an embodiment of the invention.

FIG. 6A illustrates a portion of the power stage, including the high-side FET and the low-side FET.

FIG. 6B illustrates additional details of an embodiment of a portion of the power stage, including the high-side FET and the low-side FET.

FIG. 7 shows an exemplary timing diagram of non-overlapped control signals utilized for the high-side (HS) FET and low-side (LS) FETE and the resultant switch voltage.

FIG. 8 illustrates the major functional blocks of the digital control and compensation module (CCM).

FIG. 9A illustrates a timing diagram of exemplary waveforms consistent with at least one embodiment of the invention.

FIG. 9B illustrates an expanded view of a portion of the timing diagram of FIG. 9A.

FIG. 10A is a block diagram of an exemplary portion of a current sensing circuit consistent with at least one embodiment of the invention.

FIG. 10B is a block diagram of an exemplary portion of a current sensing circuit consistent with at least one embodiment of the invention.

FIG. 10C is a block diagram of an exemplary portion of a current sensing circuit consistent with at least one embodiment of the invention.

FIG. 11A is a block diagram of an exemplary delay-locked loop consistent with at least one embodiment of the current sensing circuit of FIG. 10A.

FIG. 11B is a logic diagram of an exemplary phase detector circuit consistent with at least one embodiment of the delay-locked loop of FIG. 11A.

FIG. 12 illustrates a timing diagram of exemplary waveforms consistent with at least one embodiment of the delay-locked loop of FIG. 11A.

FIG. 13 is a block diagram of an exemplary linear regulator consistent with at least one embodiment of the delay-locked loop of FIG. 11A.

FIG. 14 is a block diagram of an exemplary track-and-hold circuit consistent with at least one embodiment of the current sensing circuit of FIG. 10A.

FIG. 15A is a timing diagram of exemplary waveforms consistent with at least one embodiment of the track-and-hold circuit of FIG. 14.

FIG. 15B is a timing diagram of exemplary waveforms consistent with at least one embodiment of the invention.

FIG. 15C is a timing diagram of exemplary waveforms consistent with at least one embodiment of the invention.

FIG. 15D is a timing diagram of exemplary waveforms consistent with at least one embodiment of the invention.

FIG. 16 illustrates a block diagram of an exemplary peak hold circuit.

FIG. 17 illustrates an open drain fault I/O configuration according to an embodiment of the invention.

FIG. 18 illustrates aspects of the fault detect block of FIG. 17.

FIG. 19 illustrates threshold sequential operation of the voltage rails.

The use of the same reference symbols in different drawings indicates similar or identical items.

### DESCRIPTION OF THE PREFERRED EMBODIMENT(S)

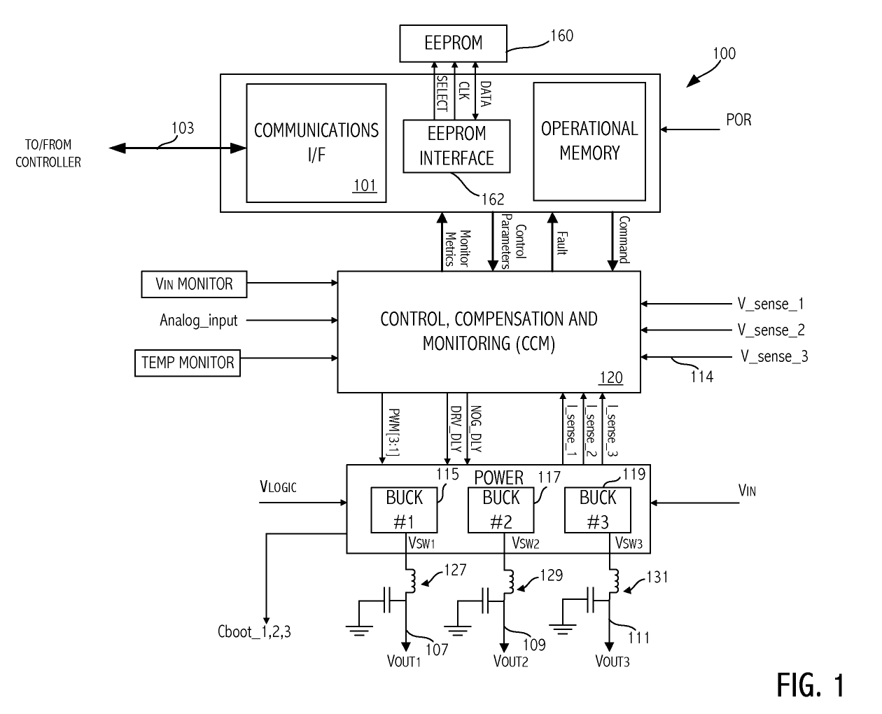

Referring to FIG. 1, illustrated is an exemplary functional block diagram of an embodiment showing a three output DC-to-DC converter 100. Converter 100 includes a communication interface 101 to communicate with a controller (not shown) over bus 103. In an embodiment, the communications interface 101 operates in accordance with the PMBus™ standard. Other embodiments may utilize a different communications interface. The communications interface is used to communicate to the converter 100 various configuration information such as the desired output voltages to be supplied on the three voltage outputs 107, 109, and 111. In addition, the converter 100 can utilize the communications interface to communicate fault information and parametric data such as output voltages and currents to the controller.

The implementation illustrated in FIG. 1 utilizes a buck topology to convert the input voltage V_{IN} 114 to the desired output voltages. Buck converter blocks 115, 117, and 119 generate three independently programmable voltage outputs. The control, compensation and monitoring (CCM) block 120 controls the buck converter blocks with appropriate duty cycle control signals, as described further herein, to ensure the appropriate voltage signals are supplied to inductors 127, 129, and 131, respectively. In that way, the desired output voltages V_{OUT1}, V_{OUT2}, and V_{OUT3} are supplied on nodes 107, 109, and 111, respectively.

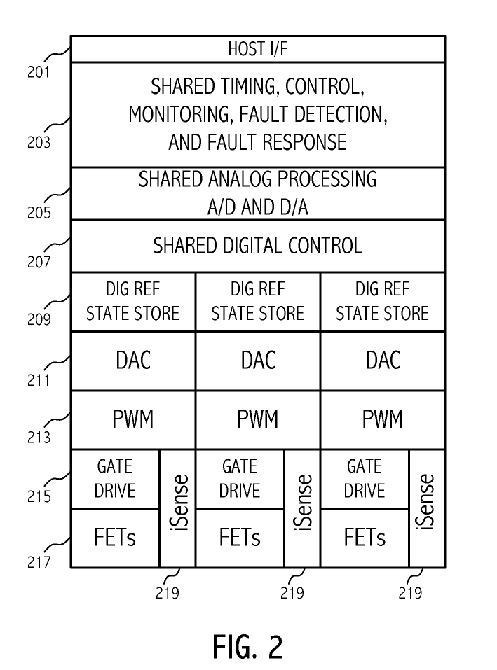

FIG. 2 illustrates high level architectural aspects of an embodiment of the invention. As shown in FIG. 2, in CCM block 120 a significant amount of the control processing is shared to allow for more efficient implementation both in terms of power and space. The host interface 201 corresponds to the interface 101. A significant amount of the timing, control, fault detection and fault response logic 203 is shared among the various outputs as described further herein. A certain portion of the analog processing, including analog-to-digital conversion and digital-to-analog conversion, is shared among the circuits generating the respective voltage outputs on a time multiplexed basis. Each output circuit utilizes a state variable stored in digital reference state store 209, which defines the duty cycle appropriate for the desired voltage for each power stage. Each power stage includes the pulse width modulation block 213 to control the duty cycle, gate drivers 215, and field effect transistors (FETs) 217, as described in more detail herein. Further, each power stage includes a current sense circuit 219. Note that while three power stages are shown in the embodiments in FIGS. 1 and 2, that number is exemplary, and other numbers of power stages may be utilized.

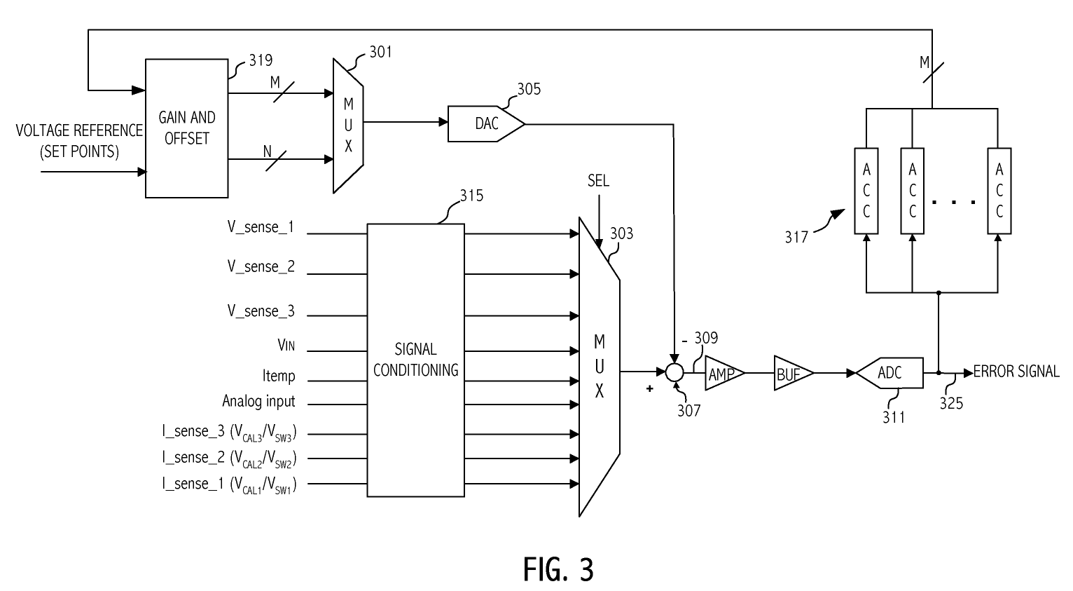

Each converter operates in a closed loop by generating a voltage based on a programmed desired output voltage, comparing the measured output voltage (and current) to the desired voltage, and adjusting the power stage by communicating an appropriate state variable to control the pulse-width of the switch voltage supplied to the inductor. One aspect of the control loop requires the comparison between set points and measured values. As mentioned above, one way to save space and power is to share logic among the N outputs where possible. Referring to FIG. 3, illustrated is one aspect of shared control logic. Multiplexer 301 receives voltage reference set point values that are programmed by the host through the host interface 101. For example, the host may specify a voltage of 0.8 volts at 4 A for output 1 and 0.8 V at 3 A for output 2 and 3.6 V at 1 A for output 3. The control for this portion of the logic ensures that the logic is shared on a time multiplexed basis. Thus, e.g., for each time slot, one of the set points (or measured values as described below) is selected by multiplexer 301 and a corresponding measured output voltage (V_sense_1, V_sense_2, or V_sense_3) is selected by analog multiplexer 303.

For example, assume that during a first time slot, the voltage set point, i.e., the desired voltage, also referred to herein as the reference voltage, is supplied by multiplexer 301. During the same time slot, the sensed voltage corresponding to that set point, i.e., V_sense_1 from the first voltage output, is supplied by analog multiplexer 303. The digital value selected by multiplexer 301 is supplied to digital-to-analog converter (DAC) 305. The DAC 305 converts the digital set point value to an analog value, which is then supplied to summing node 307. In an embodiment, the summing node 307 subtracts the set point value from the measured value and generates an error signal 309 that is amplified and supplied to an analog-to-digital converter (ADC) 311. The error signal represents the difference between the desired value and the measured value. That error is subsequently processed as described further herein to adjust the switch voltage based on the error signal.

In the second time slot, another set point and measured value is selected by the two multiplexers and an error signal corresponding to the comparison between those two signals is generated. A controller sequences through, e.g., sixteen time slots, to accommodate the various voltages.

In addition to determining the error associated with the output voltages, the same logic is utilized to support measurement of output current for each power converter stage, input current for the DC-to-DC converter 100, input voltage to the DC-to-DC converter 100, and temperature of the DC-to-DC converter 100.

For example, an initial analog value of the input voltage is supplied to signal conditioning block 315, which in turn supplies the conditioned signal to multiplexer 303. The contents of the appropriate one of the accumulators 317 with an initial zero value is supplied to gain and offset correction block 319, which is described in more detail below, and is in turn supplied to multiplexer 301. The multiplexers, in the appropriate time slot, supply the V_{IN} value and the accumulated error of V_{IN} to the summing node 307, which generates a difference signal. That difference signal is supplied to ADC 311, which converts the error signal to a digital value. That digital value is stored in the accumulator that accumulates the V_{IN} error. Initially, since the accumulator was zero, the first error signal is the measured input voltage V_{IN}. As there may be inaccuracies in the D/A and/or the A/D, it can take multiple cycles for the accumulated value to stabilize to the correct value of the signal. The sensed currents and temperature operate in a similar fashion with the accumulators. Thus, the shared logic not only is shared by the control loop but also by measured signals.

Thus, the comparisons at 307 are pipelined with the pipeline being sufficiently fast to ensure that a state variable controlling the switch voltage is updated in an appropriate time frame. In addition to the control loop for the switched voltage, the sensed variables, not used explicitly for the control loop, are also part of the pipeline operation. Even though sharing the circuitry with the sensed variables (e.g., input voltage and current, output currents, and temperature), a sufficient update rate for the state variable is accomplished to appropriately control the switch voltage. A typical power loop has a bandwidth of approximately 80 KHz so the update rate for the state variable controlling the switch voltage, at, e.g., 1 MHz, can be sufficient. While each of the signals supplied to multiplexer 301 and 303 can be updated at the same rate, e.g., at 1 MHz rate, note that certain of the signals, such as temperature, are not likely to change fast, so a much lower update rate for such a sensed variable could be implemented if necessary.

The signal conditioning block 315 may provide appropriate scaling and filtering or other signal conditioning, depending on the particular implementation, to facilitate error generation. Thus, the signal conditioning block may scale the sensed voltage to a value over which circuits can operate more linearly. Further, low pass filters may be utilized on the sensed output voltage that serve as antialiasing filters. In an embodiment, multiplexing and subtraction are done in the current domain so the signal conditioning blocks may include transconductance circuits to convert voltage values to current. In another embodiment, a switched capacitor implementation may be utilized rather than operating in the current domain.

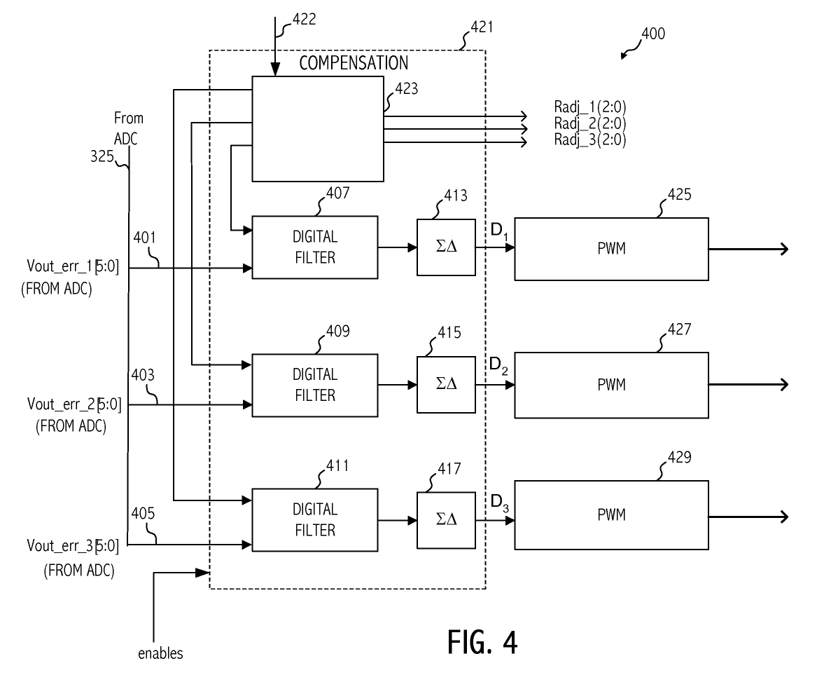

Referring now to FIG. 4, the error signal supplied by ADC 311, e.g., a 6-bit error signal, is supplied on node 325 to a controller 400 that regulates the output voltage and monitors voltage, current and temperature. The controller block maintains the output voltage as close as possible to the desired set point voltage, which has been programmed by the host through the host interface. In an embodiment, the output voltage may instead be configured to track an analog input voltage. The controller is divided into analog and digital portions. The digital portion is shown as area 421 and the analog portion is shown as the pulse-width modulators 425, 427, and 429. The controller includes a separate digital compensator for each of the power stages. Note that various logic may be shared among the digital compensators. The compensator receives the digitized error signal obtained by subtracting the setpoint voltage from a signal derived from the output of the corresponding power converter stage on signal lines 401, 403, and 405. The digitized error is processed by digital filters 407, 409, and 411, which supply the filtered error to second order sigma-delta noise shapers 413, 417, and 419. The outputs of the respective sigma-delta modulators, duty cycle state variables D1, D2, and D3 for respective power stages, are supplied to pulse-width modulator circuits 425, 427, and 429. Block 423 supplies ramp adjust signals, described below and coefficients to the digital filter. The block may receive those values over 422. The output of each sigma-delta converter is supplied to a ramp digital-to-analog converter (DAC) used in the pulse-width modulator (PWM) circuit described further below. The sigma-delta converter shapes the noise before being applied to the ramp DAC. The noise shaper takes a 16 bit output of the compensator and quantizes it to nine bits to be processed by the ramp DAC. The noise is shaped by being placed in appropriate frequencies where it is filtered by the LC circuit of the converter.

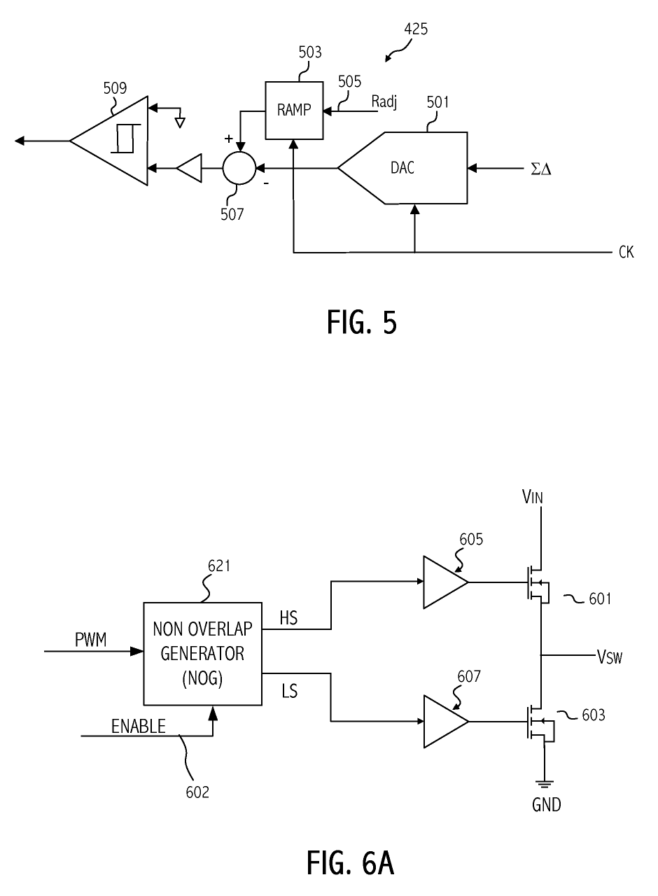

Referring to FIG. 5, a pulse-width modulator is shown in more detail. The digital signals (duty cycle state variables) supplied from the sigma-delta modulator 413 are supplied to the ramp DAC 501. The DAC converts the digitized and filtered error signal back to an analog form. The PWM is used to generate a pulse-width modulated (PWM) clock signal through comparison of the DAC output with a ramp supplied by ramp block 503, which supplies a sawtooth waveform. The ramp may be generated by passing a constant current through a capacitor. To compensate for errors in current and capacitance, an adjust value is supplied on Radj 505. Summing node 507 is used to subtract the DAC output from the ramp current The comparator 509 supplies a signal indicating when the output of the ramp generator exceeds the output of the DAC. This clock signal is used in turn to produce two non-overlapping clocks for high-side and low-side FETs, which are described below.

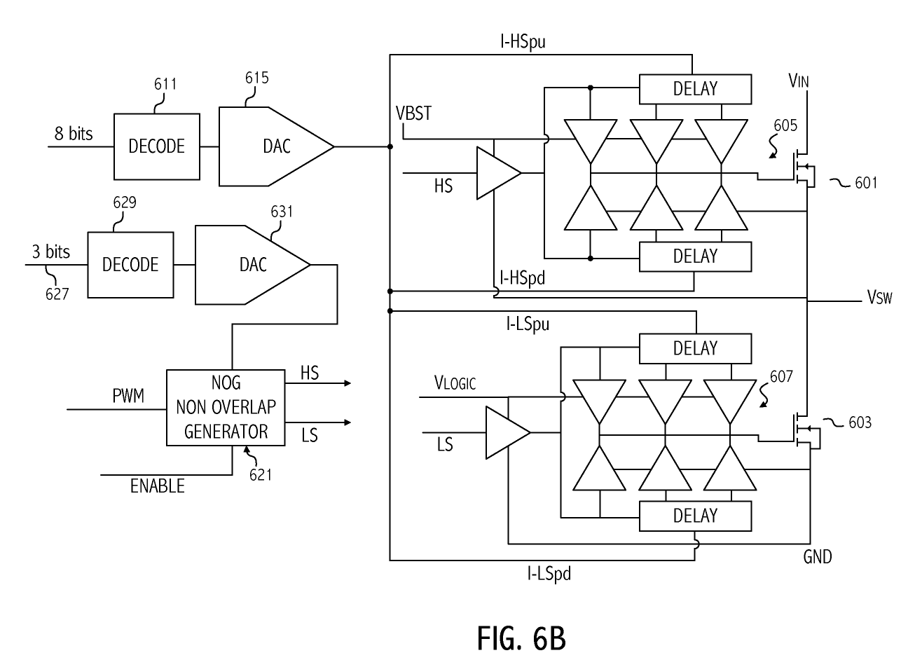

Referring now to FIG. 6A, illustrated is a high level illustration of a portion of the power stage, including the high-side FET 601 and the low-side FET 603. The high-side and low-side FETs provide paths to Vin and ground, respectively, for the switch node with the switch voltage (V_{SW}), which connects to a node of the inductor. Note that the FETs 601 and 603 are large and may be implemented as a number of smaller FETs. Drivers 605 and 607 provide sufficient drive capability for controlling the gates of the FETs 601 and 603. The pulse-width modulated signal generated by one of the pulse-width modulator circuits 425, 427, or 429 is provided to the non-overlap generator (NOG) 621, which guarantees that the high-side and low-side signals are not on at the same time.

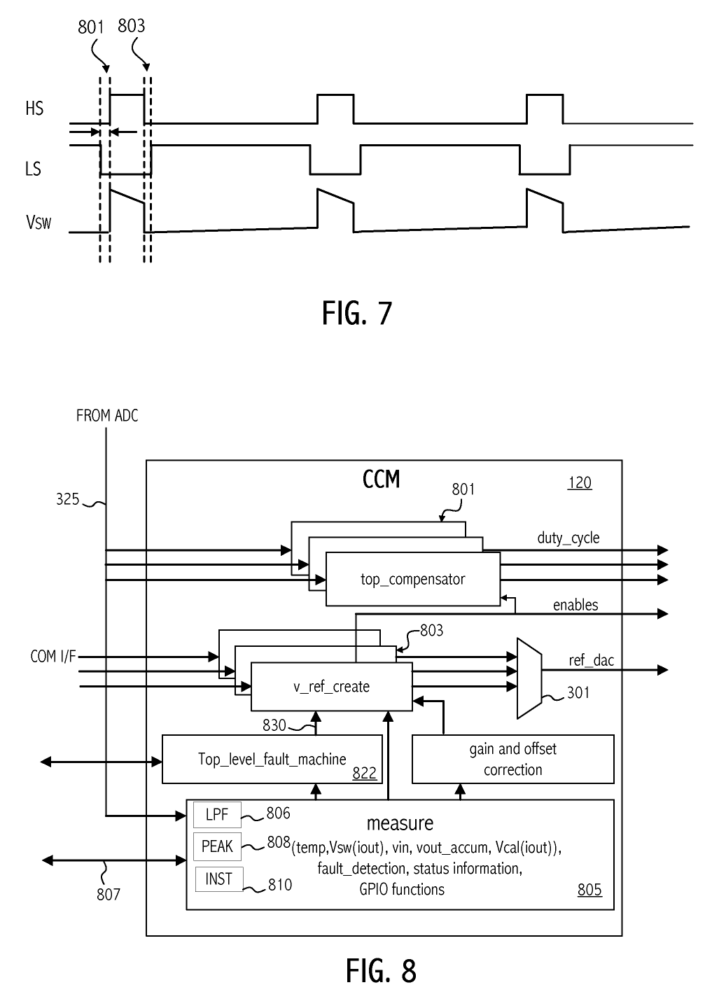

As illustrated in FIG. 6B, the drivers may include a number of drivers. In an embodiment illustrated in FIG. 6B the drivers may be turned on independently. In an exemplary embodiment, an 8-bit signal is provided to a decoder 611 and digital-to-analog converter 615 to control delay of turn-on of some or all of the drivers being used to drive the high-side and low-side FETs. The pulse-width modulated signal generated by one of the pulse-width modulator circuits 425, 427, or 429 is provided to the non-overlap generator (NOG) 621, which guarantees that the high-side and low-side signals are not on at the same time. A digital control signal can be provided on node 627 to decoder 629, which supplies DAC 631, which in turn supplies the non-overlap generator 621 with a programmable amount of non-overlap. The digital word represents the delay required between HS and LS phases. The NOG creates two phases from the supplied PWM signal. In an exemplary embodiment, the HS follows the PWM signal and the LS follows the delayed version supplied by the NOG. A delay-locked loop may be utilized to provide the required delay. In the embodiment illustrated in FIG. 6B, a bootstrap voltage circuit (not shown) may supply a bootstrap voltage (VBST) to drive the NMOS high-side FET 601. Other embodiments may use a PMOS FET. FIG. 7 shows exemplary non-overlapped control signals 701 and 703 utilized for the high-side (HS) control signal and the low-side (LS) control signal, respectively, and the resultant switch voltage.

Referring to FIG. 4, many different control algorithms can be used to provide an appropriate value to the PWM circuits to correct for detected errors. For example, in an embodiment, a proportional, integral, and derivative (PID) controller may be utilized to adjust the PWM in accordance with the error term.

Referring still to FIG. 4, in an embodiment, the digital portion of the controller includes digital filters 407, 409 and 411 that process the error terms associated with each converter output to generate the control values D₁, D₂, and D₃ being supplied to the PWM circuits 425,427 and 429.

The filter includes a fixed portion and a programmable portion. The fixed portion is a first order section that compensates the phase lag introduced by the antialiasing filter. The antialiasing filter (AAF) may be present in signal conditioning block 315 to avoid signal aliasing prior to the ADC. Usually, changes in the internal clock frequency due to temperature would affect this compensation. However, in an embodiment, the antialiasing filter (AAF) is a sampled data filter clocked at the same frequency as the digital filter. Consequently, any clock frequency variations track, in such a way that the digital filter always “sees” the same phase contribution from the AAF, making a fixed compensation section possible. That eliminates the need for programmable coefficients in the fixed portion. This fixed portion then relieves the rest of the filter from having to compensate the antialiasing filter's phase variation, so all its capability is available for compensating the phase rolloff of the plant alone. As used herein, the term “plant” means the L-C circuit comprising the switches, the inductor and any external load capacitance or combination of capacitors.

The programmable section of the digital filter implements two zeros and two poles. One of the poles is fixed at z=1, i.e., it implements a pure integrator. That feature results in zero DC error in the loop (to within offset errors). The integrator is the last stage of the filter. It is resettable, i.e., it can be loaded with an arbitrary initial value of D. This feature is useful when turning on into a prebiased load. In this case, an estimate of D can be found from the measured output voltage and loaded into the integrator. As soon as the output voltage is less than the set voltage, the compensator is turned ON and, since it contains a good estimate of the required value of D, a small transient will be produced.

The integrator is also controlled to only integrate when the output is positive or zero and to remain unchanged when the output becomes negative. This feature improves the response by precluding the need for the filter to overcome any accumulated negative values. In the control literature this is referred to as “anti-windup.”

The second pole is programmable, and can cover the entire (−1,1) range. It is implemented as a single feedback section. The two zeros also are programmable and can be real and distinct or complex conjugate. The programmable section also allows for gain adjustment, resulting in a total of 4 programmable coefficients. These features allow the filter to be used in more sophisticated control schemes as well, such as adaptive control.

The control functions that can be implemented contain the PID algorithm as a subset. It can be shown that a PID structure realizes two zeros and two poles, but the poles are fixed at z=1 (the integrator) and at z=0. There are situations where being able to cancel the effect of an equivalent series resistance (ESR) zero with a pole at a nonzero value allows the loop to have higher bandwidth and thus a better loop response, so in these cases the structure described performs better than the PID.

The programmable zeros use two coefficients. They are implemented using a structure which is quantization-insensitive, that permits the accurate implementation of coefficients that are near 1 (say 1-a, a being small) and near 2 (say 2-b, b being small), by separating the polynomial into a part which uses exactly 1 and 2 and is therefore unaffected by quantization, and another part with coefficients a and b. These can be scaled up, quantized, and scaled back down to reduce their quantization error. The results of both parts are then combined. As a result, the zeros cover a sector of the unit circle starting at some real value re(z)<1 and ending at z=1. This region of the z plane is where the zeros need to be located for compensation of the vast majority of load impedances used. A straightforward quantization of the coefficients would require a significantly larger number of coefficient bits to preserve the same resolution in the location of the zeros. This number of bits translates directly into multiplier size.

The output of the digital filter is processed by 2^{nd} Order digital Σ-Δ modulators 413, 415, 417. This block allows the use of a lower resolution DAC in blocks 425, 427, 429 to produce the analog signal which is fed to the PWM modulator. This results in large area savings. The modulator shapes the noise to higher frequencies in such a way that the noise power coupling back to the input of the control loop is minimized. The average value of the DAC output is then equal to the high-resolution value determined by the compensation digital filter.

Each sigma-delta modulator implements a zero in the noise transfer function which can be located at the frequency where the plant response has its largest peak. This feature results in gains in noise reduction of the order of 2× or larger over a regular modulator (both zeros at DC), especially for low capacitance loads. The coefficient implementing this zero can be fixed or it can be programmable according to the load. It can of course be set so the modulator has both zeros at z=1 (DC), in which case it behaves as a regular modulator.

Referring now to FIG. 8, additional details of the digital control and compensation module (CCM) 120 are illustrated. The CCM 120 includes the top compensator block 801 that receives the ADC and generates the duty cycle state variables to control the pulse-width of the control signals for the high-side and low-side FETs. The top compensator 801 (shown as 421 in FIG. 4) receives the digital value of the errors from ADC 311 and provides the appropriate duty cycle control information to the PWM circuits. The top compensator also includes v_ref_create block 803 that is responsible for the translation of commands received (e.g., over the communications interface 101) into the final digital representations for the set point voltages, which are the set point values supplied to multiplexer 301. The v_ref_create block 803 may also generate the set point voltage from an analog input voltage in response to a track command. That value is delivered to the analog circuitry for comparison with the measured value and creation of the error signal. The error signal is then delivered to the compensator block on 311 as described previously. Note that gain and offset correction may be used in generation of the reference voltage as shown.

The measure block 805 receives measurement values 807 of voltage (both input and output), input and output current, calibration, fault and status information and controls the general purpose input/output (GPIO) functionality, as described further herein. The measure block 805 may include storage for various of the measured values. The measure block can determine and store peak high and low values (PEAK) as shown in block 806, implement a low-pass filter function (LPF) and store low-pass filtered values in block 808, and store instantaneous values (INST) 810 as described further herein.

In an embodiment, faults are handled differently based on the type of fault. If the fault is based on the GPIO function, the measure block 805 supplies a fault indication on node 812 to v_ref_create 803 so the reference voltage can be turned off to turn off the output voltage.

In the illustrated embodiment, the top level fault machine 822 handles faults that are common across all of the outputs. Thus, e.g., the top-level fault machine 822 handles faults for over temperature, or a fault associated with input voltage or input current. The top level fault state machine receives data from the measure circuit block 805 and supplies a turn off signal to v_ref_create 803 on node 830 if a fault is indicated.

The v_ref_create block can handle faults that are unique to a particular output. Thus, if there is an over voltage or current on one of the blocks, v_ref_create, which receives information from the measure block on measured values, can take appropriate action to turn off the appropriate output voltage.

Note that the CCM block 120 can be implemented in application specific digital logic. In another embodiment, the CCM functionality can be implemented using a microcontroller.

### Current Sense

As described above with regard to FIGS. 1 and 2, each individual converter of converter 100 operates in a closed loop system that generates a voltage based on a programmed desired output voltage, compares a measured output voltage to the desired voltage, and adjusts the power stage by communicating an appropriate state variable to control the pulse-width of the switch voltage supplied to the inductor. Each power stage includes a corresponding current sense circuit 219 that is configured to sense the output current provided by a corresponding voltage output node (e.g., voltage outputs 107, 109, and 111). The average output current (i.e., I_{O}) delivered by the voltage output node (e.g., voltage outputs 107, 109, and 111) to a load is the average current through the inductor (e.g., inductors 127, 129, and 131) coupled to the switch pair (e.g., switch pairs in buck converters 1, 2, and 3).

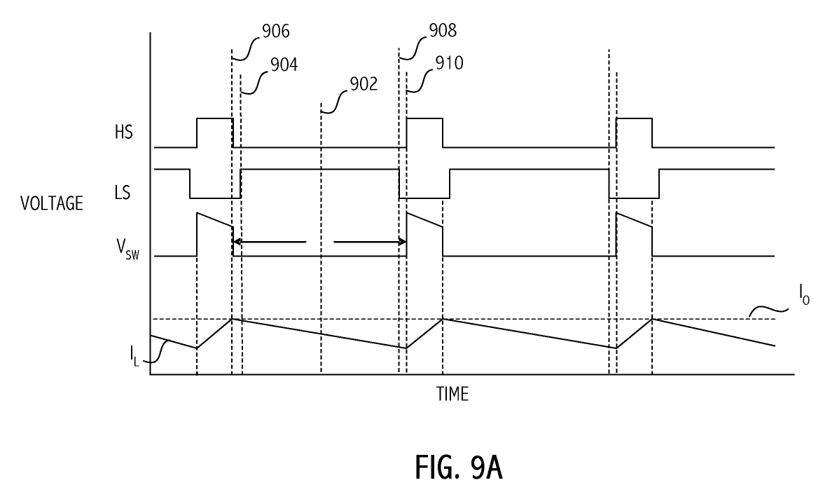

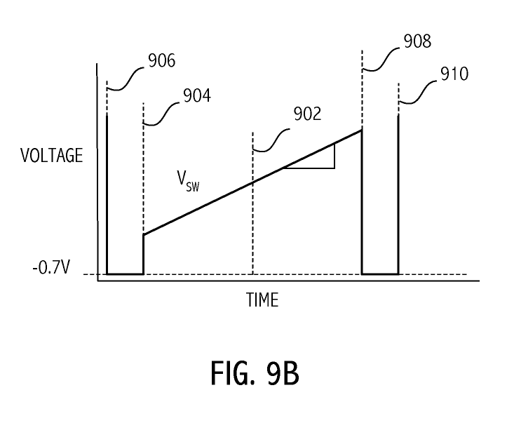

Referring to FIGS. 9A and 9B, the switch output voltage signal (i.e., V_{SW}) is a periodic signal that has a duty cycle that varies as a function of the high-side voltage (i.e., HS) and the low-side voltage (i.e., LS). An exemplary low phase of the switch output voltage signal (e.g., V_{SW} between time 904 and time 908) has a slightly sloped voltage waveform (e.g., 90 μV/ns for a 12V V_{SW} signal) when the low-side FET is on. Since HS and LS are non-overlapping, during the time when neither the low-side FET nor the high-side FET is on, the switch output node discharges current into the body diodes of the high-side or low-side FETs, resulting in notches in the V_{SW} waveform (e.g., the −0.7V notches in V_{SW} between time 906 and 904 and between time 908 and 910). The current through the inductor coupled to the switch output node (i.e., I_{L}) is equal to the average current through the inductor at the midpoint of the low phase of V_{SW} (e.g., time 902). A measurement of the current through the low-side FET at the precise mid-point of the low phase of V_{SW} is used to provide an accurate measurement (i.e., I_{SENSE}) of the average output current (i.e., I_{O}) delivered to a load coupled to the voltage output node. The value of V_{SW} is directly proportional to the resistance of the low-side FET (i.e., V_{SW}∝R_{ds}_{_{—}}_{LS}), which is unknown. To determine this value, a known current is sourced into a unit transistor matched to the N matched transistors used to form the low-side FET. A voltage across the unit transistor provides a calibration voltage (i.e., V_{CAL}) used in the determination of I_{SENSE}.

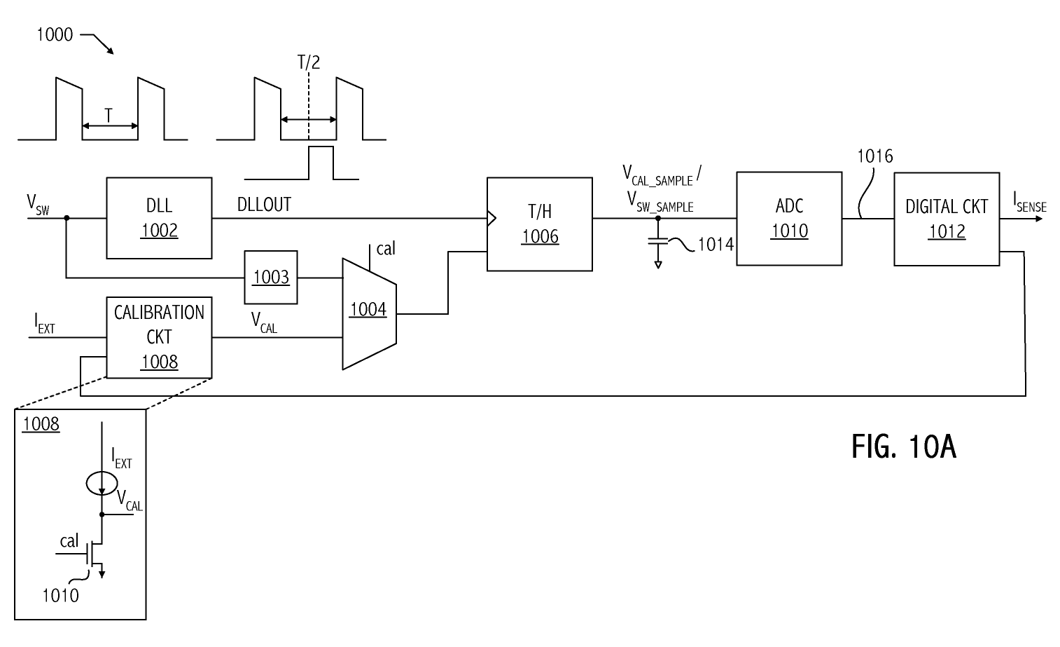

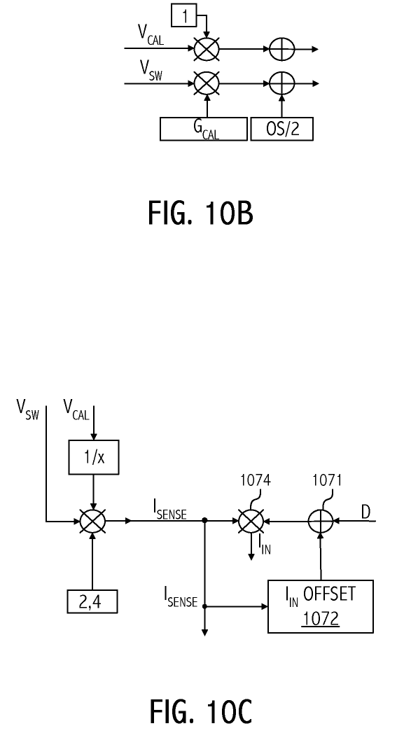

Referring back to FIGS. 1 and 2, in at least one embodiment of converter 100, at least one current sense circuit 219 includes current sensing circuit 1000 (illustrated in FIG. 10A), which senses the average output current of a corresponding voltage output node by sampling a switch output voltage signal (e.g., V_{SW}) of a corresponding switch pair (e.g., switch pairs in buck converters 1, 2, or 3 of FIG. 1 or the switch pair including high-side FET 601 and the low-side FET 603 of FIG. 6). In at least one embodiment of current sensing circuit 1000, the precise midpoint of the V_{SW} low phase may be obtained by creating a digital representation of V_{SW}. A delay-locked loop (e.g., DLL 1002) generates a sample clock signal (e.g., DLLOUT) having a transition at the midpoint of the low phase of V_{SW}. For example, where the low phase of V_{SW} has a period T, DLLOUT has a pulse transition at T/2. A track-and-hold circuit or a sample-and-hold circuit (e.g., track-and-hold circuit 1006) uses the sample clock signal to sample the V_{SW} signal at the midpoint of the low phase of V_{SW}. In at least one embodiment of current sensing circuit 1000, the sampled switch voltage signal (e.g., V_{SW}_{_{—}}_{SAMPLE}) is converted to a digital signal (e.g., using ADC 1010) and is stored in a corresponding memory element (e.g., a state element of digital circuit 1012). The calibration voltage, V_{CAL}, is generated using calibration circuit 1008, which sources a known current into a unit transistor (FET 1010) matched to the N matched transistors used to form the low-side FET. In at least one embodiment of current sensing circuit 1000, the calibration voltage is also sampled by the same track-and-hold circuit 1006, converted to a digital signal by ADC 1010, and stored in a corresponding state element of digital circuit 1012. Digital circuit 1012 determines I_{SENSE} based on the stored values of V_{CAL} and V_{SW}. Use of the same track-and-hold circuit to generate V_{SW}_{_{—}}_{SAMPLE} and V_{CAL}_{_{—}}_{SAMPLE} results in a cancellation of gain errors introduced by the track-and-hold circuit when computing I_{SENSE}, as described below.

In at least one embodiment of converter 100, rather than convert the sampled versions of V_{SW} and V_{CAL} to digital signals using ADC 1010, corresponding error signals are generated based on the sampled versions of V_{SW} and V_{CAL} and respective accumulated error signals, as illustrated in FIG. 3 for three distinct current sensing circuits (e.g., I_sense_1, I_sense_2, and I_sense_3). For example, a selected V_{CAL} or V_{SW} (e.g., V_{CAL1}, V_{SW1}, V_{CAL2}, V_{SW2}, V_{CAL3}, or V_{SW3}) is provided to summing circuit 307. Meanwhile, the value stored in a corresponding one of accumulators 317 is provided to gain and offset circuit 319 and then converted into an analog signal (e.g., by DAC 305). The analog version of the gained and offset value of the value in accumulators 317 is then subtracted from the selected V_{CAL} or V_{SW} signal to generate a corresponding analog error signal, which is then converted into a digital value (e.g., by ADC 311) and accumulated and stored in a corresponding one of accumulators 317. In at least one embodiment of converter 100, the digital version of the error signal is provided to digital circuitry (e.g., digital circuit 1012 of FIG. 10A or CCM 120 of FIG. 1).

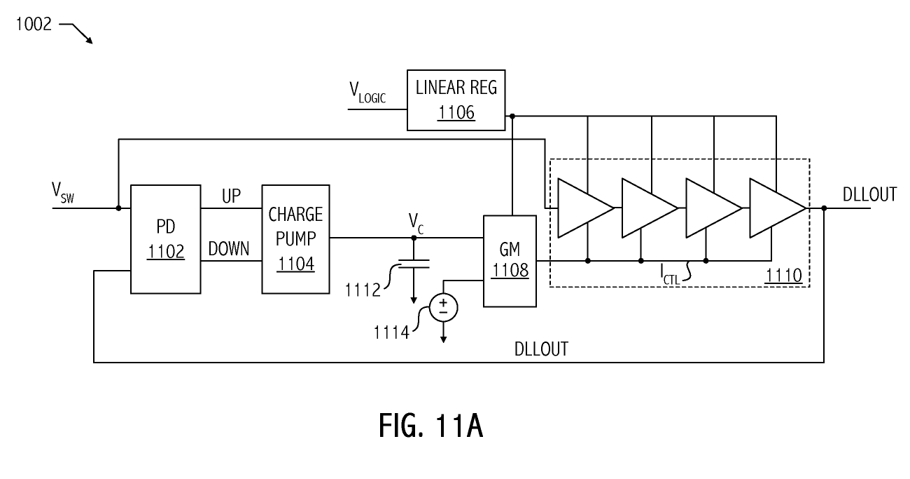

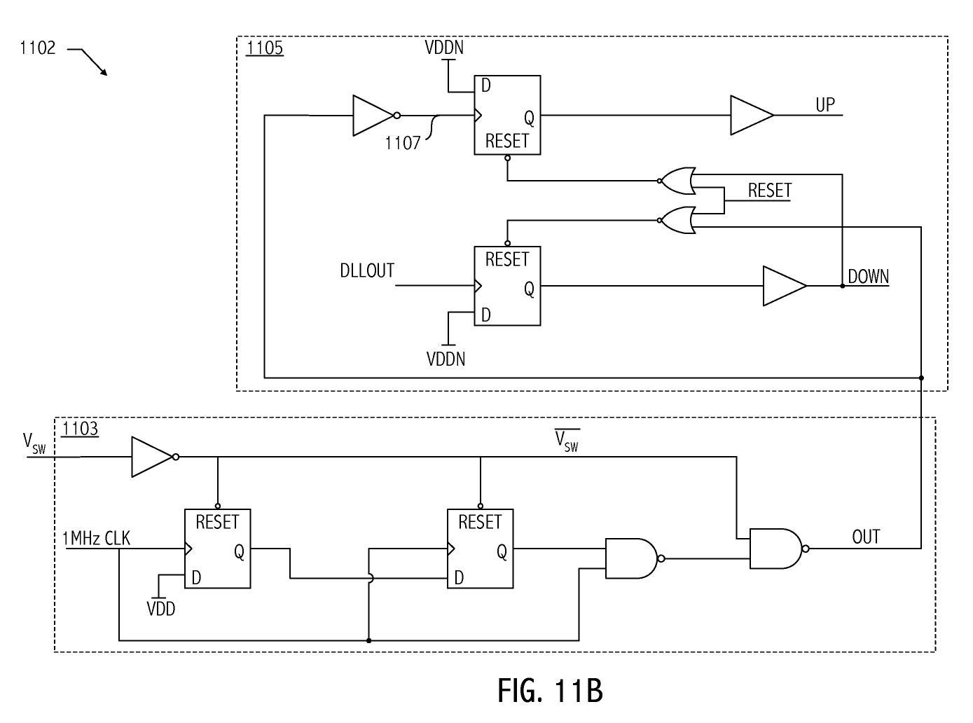

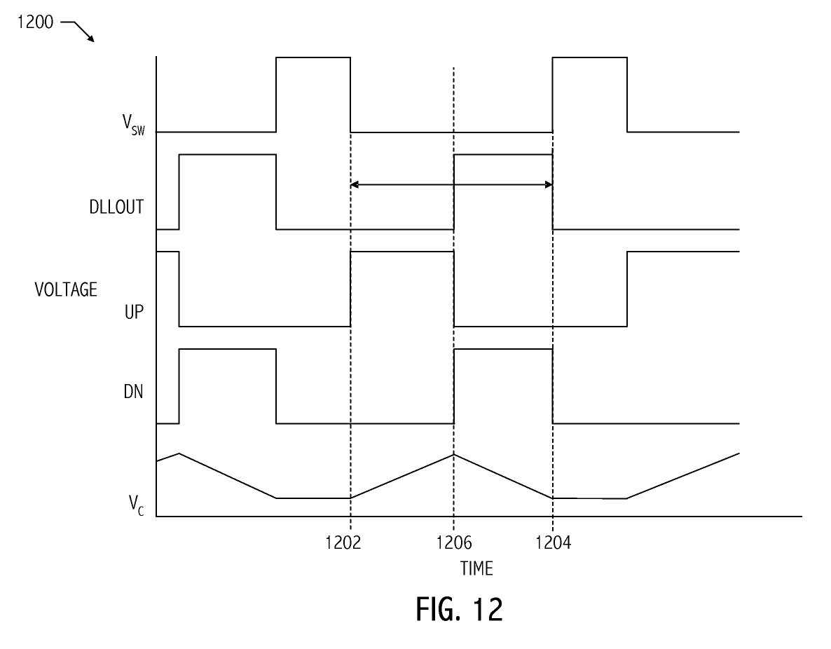

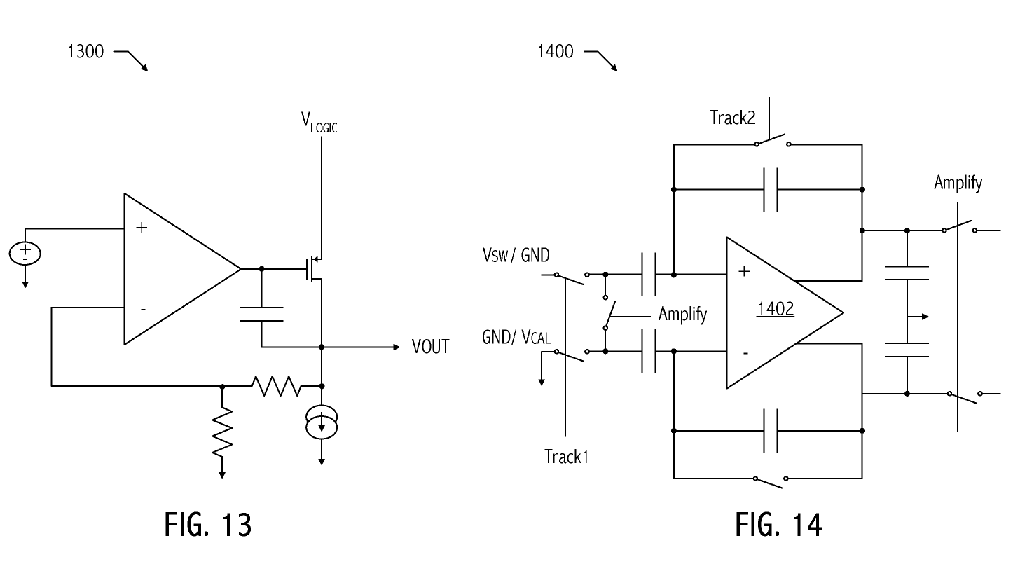

Referring to FIGS. 11A and 12, an exemplary delay-locked loop (e.g., delay-locked loop 1002) generates a clock signal (e.g., DLLOUT) having a transition at the midpoint of the low phase of V_{SW}. Phase detector 1102 compares V_{SW} to a delayed version of V_{SW} (i.e., DLLOUT) and generates at least one control signal (e.g., UP and DOWN) indicative of this comparison to adjust a delay applied to V_{SW} to obtain a rising edge of DLLOUT that coincides with the midpoint of the low-phase of V_{SW}. Referring to FIGS. 11B and 12, an exemplary phase detector circuit 1102 is illustrated, although phase detector circuit 1102 may be any suitable circuit that generates one or more control signal to adjust a delay applied to V_{SW} to obtain a rising edge of DLLOUT that coincides with the midpoint of the low-phase of V_{SW}. In at least one embodiment, phase detector circuit 1102 includes circuit portion 1103 that provides an inverted version of V_{SW} to circuit portion 1105 on OUT during normal operation. However, when the output voltage is very low, e.g., in the 100 mV range, which may occur during a startup state, V_{SW} does not include a pulse in one or more cycles. A sensed current measurement generated using V_{SW} during the time for which V_{SW} has no pulse for one or more cycles of the measurement period will be inaccurate. In at least one embodiment of converter 100, control circuit 1103 provides a substitute clock signal (e.g., CLK) to circuit portion 1105 during a time for which V_{SW} has no pulse for one or more cycles, thereby reducing error in the sensed current that may otherwise result from V_{SW} not having a pulse every cycle. In at least one embodiment of phase detector circuit 1102, circuit portion 1105 sets the UP signal high when signal 1107 transitions high (e.g., when V_{SW} transitions low during normal operation). The UP signal remains high until the DOWN signal transitions high. The DOWN signal transitions high when DLLOUT transitions high. The DOWN signal transitions low in response to a transition high of the output of circuit portion 1103 (e.g., when V_{SW} transitions high, during normal operation).

Referring back to FIGS. 11A and 12, in at least one embodiment of delay-locked loop 1002, a charge pump (e.g., charge pump 1104) delivers charge to a node V_{C} coupled to a capacitor (e.g., capacitor 1112) when a first control signal is high (e.g., UP=‘1’) and a second control signal is low (e.g., DOWN=‘0’), and sinks current from V_{C} when the second control signal is high (e.g., DOWN=‘1’) and first control signal is low (e.g., UP=‘0’). In at least one embodiment of delay-locked loop 1002, when both UP and DOWN are low, the voltage on V_{C} is maintained at a constant voltage level.

In at least one embodiment of DLL 1002, to obtain a rising edge of DLLOUT that coincides with the midpoint of the low-phase of V_{SW}, when the rising edge of DLLOUT occurs after the midpoint of the low phase of V_{SW}, and occurs before the rising edge of V_{SW}, an exemplary phase detector 1102 sets the UP and DOWN control signals to configure charge pump 1104 to source current to capacitor 1112 for a longer period of time than the period of time that charge pump 1104 sinks current from capacitor 1112. In at least one embodiment of delay-locked loop 1002, when V_{SW} is high, phase detector 1102 sets both of the UP and DOWN outputs to low. If capacitor 1112 receives charge from charge pump 1104 for a longer period of time than the period of time that charge pump 1104 discharges capacitor 1112, the average voltage on V_{C} increases. An amplifier circuit (e.g., transconductance amplifier 1108) senses a voltage difference between the voltage on V_{C} and a predetermined voltage level (e.g., approximately 1V) provided by voltage reference 1114 (e.g., a bandgap voltage reference or replica voltage reference) and generates a current (i.e., I_{CTL}) at the output proportional to that voltage difference. An increase in I_{CTL} decreases the delay through delay line 1110 and decreases the delay of V_{SW} to generate DLLOUT having a high transition at the mid-point of the low phase of V_{SW}.

When the DLLOUT rising edge occurs before the midpoint of the low phase of V_{SW}, and occurs after the falling edge of V_{SW}, phase detector 1102 sets the UP and DOWN control signals to configure charge pump 1104 to sink current from capacitor 1112 for a longer period of time than the period of time that charge pump 1104 sources current to capacitor 1112. If capacitor 1112 receives charge from charge pump 1104 for a shorter period of time than the period of time that charge pump 1104 discharges capacitor 1112, the average voltage on V_{C} decreases. Transconductance amplifier 1108 senses the difference between the voltage on V_{C} and the predetermined voltage level provided by voltage source 1114 and sets I_{CTL} to have a current proportional to that voltage difference. The current I_{CTL} adjusts the delay of individual delay elements of current-controlled delay line 1110 accordingly. A decrease in I_{CTL} increases the delay through delay line 1110 and increases the delay of V_{SW} to generate DLLOUT having a high transition at the mid-point of the low phase of V_{SW}.

Accordingly, delay-locked loop 1002 regulates the delay through current-controlled delay line 1110 until the rising edge of DLLOUT occurs at the midpoint of the low phase of V_{SW}. Note that rather than delaying V_{SW} by a full clock period as in typical delay-locked loops, current-controlled delay line 1110 delays V_{SW} by substantially less than a full period of V_{SW}. In at least one embodiment, delay-locked loop 1002 generates a rising edge corresponding to a falling edge of V_{SW} delayed by half the period of the low phase of V_{SW}. In at least one embodiment of delay-locked loop 1002, current-controlled delay line 1110 is susceptible to noise introduced by a power supply node (e.g., V_{LOGIC}) coupled to current-controlled delay line 1110, which results in jitter on DLLOUT. Accordingly, linear regulator circuit 1106 is included to attenuate the noise introduced by the power supply node and thereby reduce jitter on DLLOUT. Note that although a transconductance amplifier circuit and a current-controlled delay line are used, other suitable amplifier and delay line circuits may be used. However, use of a transconductance amplifier circuit and a current-controlled delay line may reduce noise and improve the associated power supply rejection ratio as compared to other amplifiers and delay line circuits.

Referring back to FIG. 10A, in at least one embodiment, current sensing circuit 1000 includes a calibration circuit (e.g., calibration circuit 1008) to generate a value for 1/R_{ds}_{_{—}}_{LS}. Calibration circuit 1008 uses a precise (e.g., low temperature coefficient), known current (e.g., a zero temperature coefficient bandgap current, I_{EXT}) and a copy of the low-side FET. A digital calibration factor is used to obtain a correct value for I_{EXT}*R_{DS}. The copy of the low-side FET may be smaller than the actual low-side FET by a multiplier. For example, FET 1010 matches individual ones of N matched transistors used to form the low-side FET 603 of FIG. 6, but is only approximately 1/1000 the size of low-side FET 603. In at least one embodiment of current sensing circuit 1000, calibration circuit 1008 is activated for only sixteen consecutive cycles once every 1025 cycles of a 1 MHz clock signal, although in other embodiments calibration circuit 1008 may always be activated. Select circuit 1004 is configured to select V_{CAL} periodically for sampling by track-and-hold circuit 1006 and conversion into a digital value by analog-to-digital converter 1010. The digital value may be stored in a state element of digital circuit 1012, which uses that value to determine I_{SENSE}.

In at least one embodiment, current sensing circuit 1000 includes a level converter circuit (e.g., voltage clamp block 1003) that converts the switch output voltage signal from a 12V signal into a logic-level signal (e.g., by clamping a 12V signal to 3.3V) having the same pulse-width as the output of the switch. Select circuit 1004 selectively couples V_{SW} or V_{CAL} to a sample-and-hold or a track-and-hold circuit (e.g., track-and-hold circuit 1006) according to the value of a calibration control signal (e.g., cal). Note that although level shift block 1003 and select circuit 1004 are illustrated as a separate circuits, in at least one embodiment of current sensing circuit 1000, level shift block 1003 and select circuit 1004 are omitted, and the functionality of level shift block 1003 and select circuit 1004 is incorporated into one or more other circuits of current sensing circuit 1000.

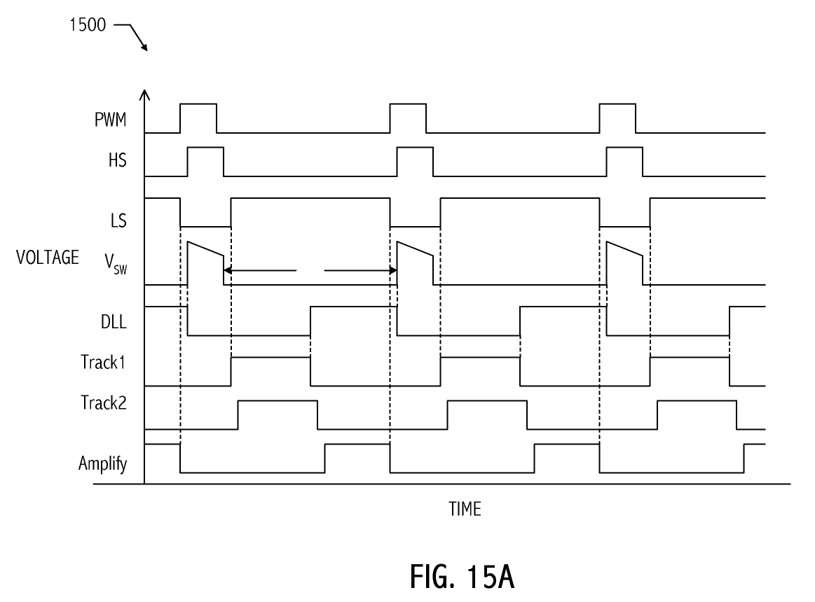

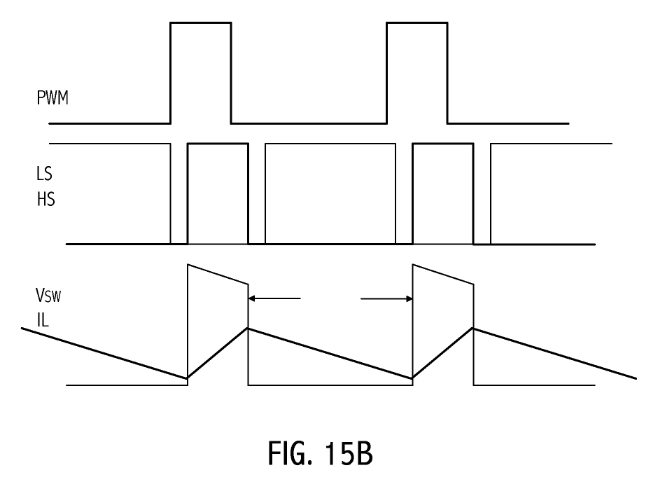

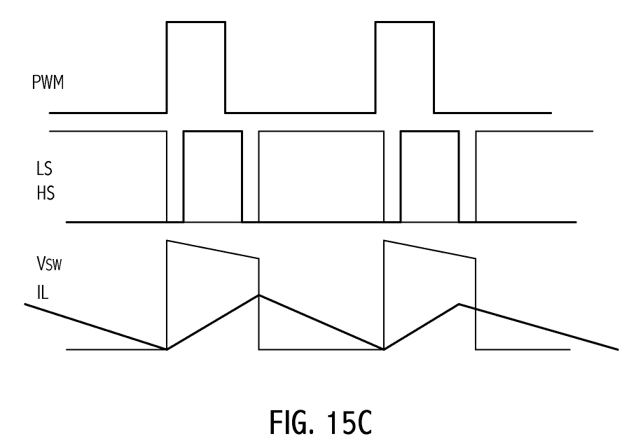

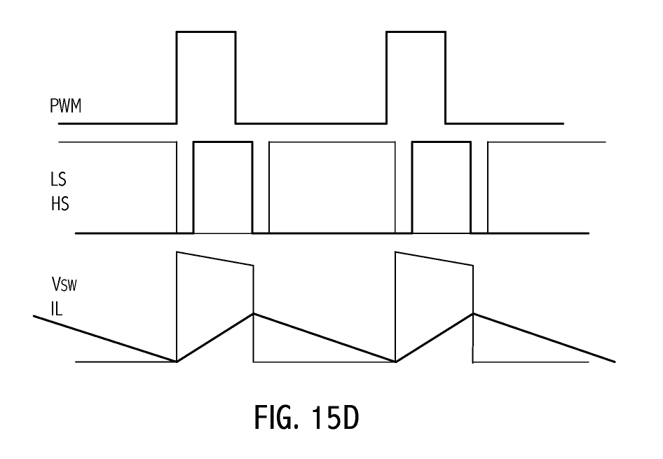

Referring to FIGS. 14 and 15, in at least one embodiment of current sensing circuit 1000, track-and-hold circuit 1400 separately samples V_{SW} and V_{CAL} and amplifies those signals by a predetermined amount (e.g., 7×). For example, track-and-hold circuit 1400 may consistently sample V_{SW} according to the sample clock signal and periodically sample V_{CAL} after a predetermined number of sample clocks (e.g., every millisecond) to calibrate for temperature drift. In at least one embodiment, track-and-hold circuit 1006 has a track phase that tracks the input and stores a corresponding value on a sampling capacitor. In an amplify phase, the input is disconnected from the sampling capacitor. In at least one embodiment of track-and-hold circuit 1006, control signals Track1 and Track2 are slightly shifted in time to reduce charge injection into the sampling capacitor from corresponding switches.

Referring back to FIG. 10A, in at least one embodiment of converter 100, the sampled outputs of track-and-hold circuit 1006 are provided to analog-to-digital converter 1010, which generates digital versions of the sampled calibration voltage and the sampled switch output voltage signal. Those digital values of V_{CAL} and V_{SW} are stored in digital registers of digital circuit 1012 for digital processing. However, in at least one embodiment of converter 100, corresponding error signals are generated instead, as described above with regard to FIG. 3.

The following relationships characterize the system:

$${V}_{SW} = {I}_{OUT} \times {R}_{LS}$$

$${V}_{CAL} = {I}_{REF} \times α \times {R}_{LS} \times β$$

$$M = {I}_{REF} \times α \times \frac{{R}_{CAL}}{{R}_{LS}} = {I}_{REF} \times α \times β$$

$$Setting M = 2 ( {I}_{REF} \approx 20 μ A ) , \\ \frac{{V}_{SW}}{{V}_{CAL}} = \frac{{I}_{OUT} \times {R}_{LS}}{2 \times {R}_{LS}} , \\ {I}_{OUT} = \frac{{V}_{SW} \times 2}{{V}_{CAL}} , \\ {I}_{IN} = {I}_{OUT} \times D .$$

In at least one embodiment of current sensing circuit 1000, α, the ratio of a mirrored version of the reference current (i.e., I_{MREF}) to the reference current (i.e., I_{REF}) is 108 (i.e., I_{MREF}=αI_{REF}). In at least one embodiment of current sensing circuit 1000, β, the ratio of the size of the LS FET to the calibration FET is 960 (i.e., R_{CAL}=βR_{LS}). Note that in other embodiments of current sensing circuit 1000, M is set to other values according to the target semiconductor manufacturing process and a target application.

Error in the actual ratio may be corrected for using gain and offset correction techniques. Although gain and compensation techniques may be applied after computing an I_{SENSE} value, in at least one embodiment of current sensing circuit 1000, gain and compensation techniques are applied to V_{SW} and V_{CAL} prior to determining the I_{SENSE} value, i.e., prior to dividing V_{SW} by V_{CAL}. For example, referring back to FIG. 3, gain and compensation techniques may be applied to the accumulated V_{CAL} or V_{SW} error values stored in a corresponding one of accumulators 317 of FIG. 3 by gain and offset circuit 319. Referring to FIG. 10B, in at least one embodiment of converter 100, a gain value (e.g., G_{CAL}) is applied to only V_{SW} to correct for errors in the ratio M. Meanwhile, a unity gain may be applied to V_{CAL}. Thus any error introduced by the multiplication will cancel later when V_{SW} is divided by V_{CAL}. In at least one embodiment of converter 100, a single offset value (e.g., OS_{CAL}) is applied to the I_{SENSE} computation by adding an offset value (e.g., OS/2) to the accumulated value of the V_{SW} error signal and subtracting that same offset value (e.g., OS/2) from the accumulated value of the V_{CAL} error signal. The values of OS_{CAL} and G_{CAL} may be determined experimentally, e.g., by setting a known output current and measuring the value for I_{SENSE} that is reported by current sensing circuit 1000. Using the known output current value and the measured I_{SENSE}, values of OS_{CAL} and G_{CAL} are determined and stored in EEPROM in the part. Accordingly, OS_{CAL} and G_{CAL} values may be used to compensate for temperature, process, and voltage variations.

Referring back to FIG. 10A and FIG. 3, note that the loop stabilizes, i.e., the error between V_{CAL} and V_{SW} and their corresponding accumulated values eventually becomes zero. Once the loop stabilizes, the corresponding error signals are zero and the respective values in accumulators 317 no longer change, i.e., the accumulated error values corresponding to V_{CAL} and V_{SW} equal corrected values (e.g., corrected by gain and offset values) of V_{CAL} and V_{SW}, respectively. In at least one embodiment of converter 100, the values of V_{CAL} and V_{SW} stored in accumulators 317 are used (e.g., by digital circuit 1012 or CCM 700) to determine I_{SENSE} and I_{IN} (i.e., the input to calibration circuit 1008). Note that in other embodiments of converter 100, digital versions of V_{CAL}_{_{—}}_{SAMPLE} and V_{SW}_{_{—}}_{SAMPLE} signals 1016 of FIG. 10A are used instead of the values in accumulators 317.

Referring to FIG. 10C, I_{SENSE} and I_{IN} are determined according to the following relationships:

$${I}_{SENSE} = \frac{{V}_{SW} \times k}{{V}_{CAL}} ;$$

$${I}_{IN} = {I}_{SENSE} \times {D}_{VSW} ,$$

where I_{IN} is the input current of converter 100 and D is the duty cycle of the V_{SW} pulse. In at least one embodiment of converter 100, the reciprocal of the value of V_{CAL} in accumulators 317 and the value of V_{SW} stored in accumulators 317 are multiplied and the product is multiplied by a constant value (e.g., 2 or 4), which is selected based on the configuration of the particular converter. The resulting value of I_{SENSE} is

$${I}_{SENSE} = \frac{k}{1 - {G}_{CAL}} [ \frac{- {V}_{SW} + OS}{{V}_{CAL} - OS} ]$$

Note that I_{SENSE} may be positive or negative, depending upon whether the converter sources or sinks current to or from a load coupled to converter 100. Accordingly, the value of V_{SW} is positive when sinking current to the load and is negative when sourcing current from the load. Referring to FIG. 14, in at least one embodiment of converter 100, the V_{SW} signal is provided to the non-inverting terminal of amplifier 1402 (which provides a 1V differential output), to account for positive and negative output current values. However, V_{CAL}, which is always positive, is provided to the inverting terminal of amplifier 1402. Accordingly, a minus sign appears in front of V_{SW} in the equation for I_{SENSE}. Note that this is not a digital correction, but rather is a correction applied in the analog domain.

In at least one embodiment of current sensing circuit 1000, the duty cycle of the V_{SW} pulse is determined using a duty cycle of the signal PWM of FIG. 6A (e.g., at least partially based on a duty cycle state variable D stored in digital reference state store 209). However, the actual duty cycle of the PWM signal (i.e., D_{PWM}) is different from the actual duty cycle of V_{SW} (i.e., D_{VSW}) because during the time that both the LS and HS signals are low (i.e., non-overlap time NOG), neither the high-side FET nor the low-side FET is on, and diodes in the high-side FET and low-side FET may source or sink current to/from the load. Thus, the offset between D_{VSW} and D_{PWM} may be determined according to the value of the load current, I_{SENSE}. Accordingly,

I_{IN}=(I_{SENSE}×(D_{PWM}+D_{OS}))+I_{OH},

where D_{OS} is the offset determined according to the value of the load current, I_{SENSE}, and I_{OH} is an overhead current value, e.g., a current value that accounts for driving the power stage and a/c loss in inductors.

For example, referring to FIG. 15B, when I_{SENSE} has a positive, high magnitude current (i.e., the magnitude of I_{SENSE} is greater than the inductor ripple current, |I_{SENSE}|>I_{RIPPLE}), diodes in the low-side FET sink current from the load. Accordingly, D_{VSW}≈D_{PWM}. Referring to FIG. 15C, when I_{SENSE} has a negative, high magnitude current, current flow is generated by diodes in the high-side FET. During the non-overlap time, V_{SW} remains high until the low-side FET turns on. Accordingly, D_{VSW}≈D_{PWM}+(2×NOG). Referring to FIG. 15D, when I_{SENSE} has either a positive or negative, medium or low magnitude current (i.e., |I_{SENSE}|<I_{RIPPLE}), D_{VSW}≈D_{PWM}+(NOG). Offset corrections for all three conditions may be introduced based on the I_{SENSE}. Referring to FIG. 10C, in at least one embodiment of current sensing circuit 1000, I_{IN} OFFSET 1072 selects an appropriate offset value, which may be stored in corresponding registers, based on the sign and/or magnitude of I_{SENSE}. The sum of the selected offset value and a value corresponding to the duty cycle of PWM are multiplied by I_{SENSE} to generate I_{IN}. Where multiple power converters reside on a single power converter integrated circuit, an output current and an input current may be separately determined for each power converter. A total input current for converter 100 may be determined by summing the corresponding values of I_{IN}. For example, the summation of I_{IN1}, I_{IN2}, and I_{IN3} may occur in CCM 120 of FIG. 1 to generate a total value of I_{IN}. The computed values of I_{IN} and I_{OUT} may be used to detect faults and may be reported externally to converter 100.

Referring back to FIG. 10A, in at least one embodiment of current sensing circuit 1000, a digital low pass filter (e.g., 10 kHz low pass filter) is applied to the sensed output current (i.e., I_{SENSE}) to reduce the effects of external noise and internal round-off errors on the computed current. A value of I_{IN} is computed from the I_{SENSE} and the duty cycle D. Division of V_{SW} by V_{CAL} reduces or eliminates some sources of error. The technique for sensing the average output current described herein improves the accuracy of the measurement to within 100 mA for a 5-Amp current.

The description of the current sensing circuit set forth herein is illustrative, and is not intended to limit the scope of the invention as set forth in the following claims. For example, while the current sensing circuit has been described in an embodiment in which a buck converter circuit is used and a node of the buck converter circuit is sampled at the midpoint of a low-phase of the signal on the node, one of skill in the art will appreciate that the teachings herein can be utilized with other power converter circuit topologies (e.g., boost, buck-boost, push-pull, full-bridge, half-bridge, flyback, Cúk, forward, or other suitable converter circuit topologies) and corresponding nodes of the other converter circuits are sampled at appropriate points of respective signals on the corresponding nodes (i.e., where the current through an inductor coupled to the corresponding node is equal to the average current through the inductor). Variations and modifications of the embodiments disclosed herein, may be made based on the description set forth herein, without departing from the scope and spirit of the invention as set forth in the claims below.

### Monitoring Functions

In order to provide the host controller connected to the voltage converter with data regarding operation of the voltage converter, a variety of data may be monitored and stored by the voltage converter. For example, the voltage converter monitors the input voltage (V_{IN}), the input current (I_{IN}), V_{OUT} for each of the power output stages (V_{OUT1}, V_{OUT2}, V_{OUT3}), I_{OUT} for each of the outputs (I_{OUT1}, I_{OUT2}, I_{OUT3}), and the temperature T of the device. In an embodiment, these values are continuously monitored. In addition to sensing the voltages, currents, and the temperature described above, in an embodiment, various processing may be performed on the sensed parameters.

For example, in an embodiment, peak high and peak low values may be determined for the sensed parameters. Thus, a command may be sent over the communications interface requesting, e.g., the peak high voltage for V_{OUT}. In an embodiment, the execution of the command provides the peak high value from the last time the command was received, or power-up. That value may then be returned over the communications interface. Execution of the command may cause the peak value to be reset to the current value, and a new time interval for peak measurement is defined. On a subsequent execution of the command, the peak value for the time period between the last execution and the current execution of the command is provided.

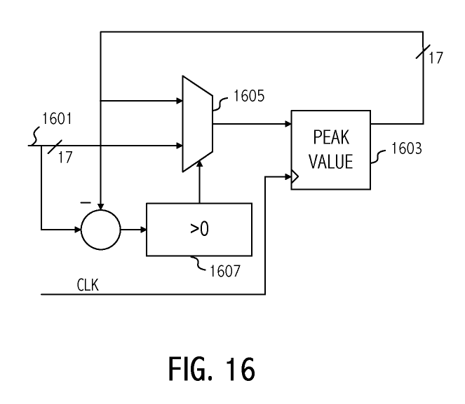

FIG. 16 shows a block diagram of an exemplary peak hold circuit that may be utilized. In an embodiment, the peak hold circuit is implemented in measure block 805. The current sensed value is supplied on node 1601 and is compared to the current peak value in storage elements 1603 by subtracting the current peak value from the current sensed value. If the subtraction results in a value greater than zero, then the selector circuit 1605 selects the current sensed value as the next value for the peak value storage elements 1603. On each execution of the command, the peak value may be forced to the current sensed value by overriding logic 1607. Note that while each sensed voltage and current measurement may have its own peak value circuit, in other embodiments, the peak value circuit, other than the peak value storage elements storage and the peak value measurement, may be shared on a time-multiplexed basis. A peak value measurement may be stored for each voltage, current, and temperature measurement. In addition to a peak high measurement circuit, a peak low (the lowest value) may be determined. The operation of the circuit is similar to that in FIG. 16 except the stored peak low value is replaced when the stored peak low value is higher than the current sensed value.

In addition to the peak value measurements, the instantaneous voltage, current, and temperature measurements may be sensed and stored by the voltage converter. The measured signals (input voltage and output voltages, input current and output currents and temperature) may be supplied to memory circuits in measure block 805, peak value measurement circuits, and/or to a low pass filter circuit 806 (FIG. 8). The low pass filter circuit provides an average value of the particular measurement of interest. A separate low pass filter circuit may be provided for each measurement for which such a filtered value is desirable. The instantaneous values may be stored in operational memory 140 (FIG. 1). Arithmetic circuits used in calculation of peak high, peak low, and low pass filtering may be shared on a time-multiplexed basis. A command may be sent from the host to the communications interface to retrieve a low pass filtered or average value of one of the measured parameters, instantaneous values, peak high or peak low values.

In addition to commands to obtain low pass filtered values, instantaneous values, and peak high or peak low values, a strobe command may be issued by the host to obtain time correlated measurements of parameters associated with all the outputs and all common parameters. The decode of the command causes time correlated measured values associated with all of the power outputs to be stored so they can be made available to the host. The values may be returned as a result of a command decode of the strobe command or the transaction may be split so that one or more subsequent read commands may be required to return the time correlated data. Note that in an embodiment, the time correlated data is not from exactly the same time, since shared logic may be used to generate the digital values that are stored and returned. However, assuming, e.g., that the multiplexer 301 and 303 switch inputs at 16 MHz, the returned values are correlated within less than one microsecond of each other. Given that the bandwidth of the power supply loop is relatively low, e.g., 80 KHz, the time correlation is sufficient for most purposes. Note that in an embodiment, the strobe command may specify all measured voltage, current and temperature, both instantaneous, low pass filtered and peak high and peak low. In other embodiments, time correlated data for any or all of the sensed data may be specified in the command and returned to the host over the communications interface. Thus, in an embodiment, the strobe command can specify one or more of instantaneous values, low pass filtered values, peak high, or peak low values for any plurality of or all of the rails. In an embodiment, the values to be stored by the strobe command may be programmable. For example, a command may be received over communications interface 101 (FIG. 1) with a bit field specifying one or more of the measured values for one or more of the rails to be stored in response to the strobe command. In other embodiments, the particular time correlated data that is stored may be fixed rather than programmable.

In an embodiment a strobe event storing time correlated data may occur in response to a condition or occurrence in the device other than the strobe command, e.g., when an update has occurred to the peak high or peak low registers. That is, when the peak high or peak low registers are updated, time correlated data is stored. That data may be made available to the host via a subsequent read command. Thus, a strobe event storing time correlated data may occur in response to a received command or to some other occurrence. For example, a strobe event may be programmed to occur in response to an over-temperature condition or other detected fault. In an embodiment, the condition(s) that trigger a strobe event, along with the time correlated data that is stored, may be programmable.

### Fault I/O and GPIO

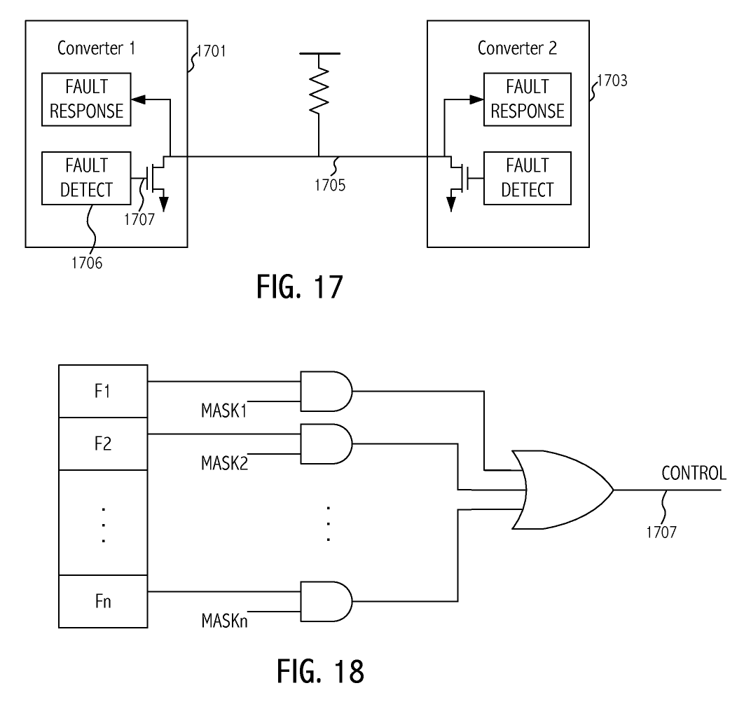

In complex power systems, there are multiple rails provided by separate components on the board. Thus, there may be more than one voltage converter providing multiple rails. Each rail and/or each converter may have its own fault detection/response mechanisms. Thus, for example, in an embodiment, one of the rails may be particularly sensitive to an under voltage fault and another rail to an over voltage fault. As shown in FIG. 17, an open drain device is utilized so either converter 1701 or converter 1703 can pull down the fault line 1705. In addition, as shown in FIG. 17, the fault or faults detected that cause fault detect to be active and pull down fault line 1705 can be programmed. As shown in FIG. 17, fault detection logic 1706, in addition to comparison of the sensed values to an appropriate threshold to determine presence of a fault, may also allow programming of which fault(s) cause control value 1707 to be active, thus pulling down fault line 1705. A group of general purpose input/output (GPIO) terminals may be programmed to be fault I/O terminals or other types of terminals (inputs and/or outputs), as described more fully below. The control of the GPIO terminals may be provided in the measure block 805. As shown in FIG. 18, a particular fault or group of faults (F1 to Fn) may, by using appropriate mask values MASK1 to MASKn from a fault mask register (not shown), cause the control line 1707 to be activated. Thus, an over voltage condition on a power rail in converter 1 may cause converter 1701 to pull down the fault line 1705 while a separate fault or group of faults (F1 to Fn) may cause converter 2 1703 to activate fault detect and pull down fault line 1705. In addition, each converter can be programmed to have a specific fault response. The fault response may be programmed over the communications interface. For example, converter 1701 may be programmed to shut down on activation of fault line 1705 caused by any fault. Converter 1703 may be programmed to ignore fault line 1705. Thus, converters may be programmed to be drive only, i.e. publish faults, or listen only with respect to fault line 1705, or to both drive and listen to the fault line. Although only two converters are shown for illustration, additional converters may be connected to the fault line 1705. In addition to identifying the faults to detect, the threshold values may be programmed for comparison to the sensed values in order to determine the presence of a fault. Further, multiple voltage rails may be programmed to drive one of the fault I/O lines. Thus, all (or fewer) of the power rails V1 and V2 may drive one of the fault I/O terminals. Thus, a fault line may be provided for each power rail, or alternatively, any fault on any one or group of the power rails may be configured to drive a single fault I/O terminal. Note that in embodiments, faults may be logged in non-volatile memory when they occur. Thus, even though activation of the fault line does not allow fault isolation, since anyone connected to it may activate the line, interrogation of the logged faults allows fault isolation.

In an embodiment, one or more general purpose input/output terminals may be provided that can individually be programmed to be a fault line as described above, a power good terminal, an analog input ready, or to drive and listen to digital data. The power good signal, indicating that one or more voltage rails has reached a programmable threshold voltage, is configurable to specify which power rail or group of power rails has reached its voltage. Thus, all three power rails (or fewer) may be tied to one power good output signal, or each GPIO can be a power good signal tied to its own power rail. The polarity of the power good signal may also be configurable. The analog input ready signal, in which a GPIO terminal is configured as an output signal, indicates that the device is ready to accept an analog input signal.

### Fault Logging

Referring again to FIG. 1, when a fault is detected by any of the fault detection mechanisms, the fault is logged in the EEPROM 160 through EEPROM interface 162. In an embodiment, the EEPROM is implemented off chip. In addition to logging the fault, all parametric data available is also logged in the EEPROM. Thus, in an over voltage vault is detected on V_{OUT3}, all of the parametric data available for all of the outputs is stored in the EEPROM. The data can include temperature, input voltage, output voltages, output currents, input current and associated peak high and low, low pass filtered values, and instantaneous values (the latest measured value) at the time of the fault. That can help in isolating and identifying the real cause of the fault. In an embodiment, a second occurrence of a fault, within a predetermined time period, may just cause the fault to be logged by itself. In other embodiments, for every fault detected, all available data is logged in EEPROM.

### PreBias on Output

Referring again to FIG. 1, the output voltage supplied on, e.g., node 107 is typically specified to have a particular ramp time from the zero voltage level to the target voltage. However, in certain circumstances a voltage may be present on the output node already. When that occurs, one embodiment of the DC-to-DC voltage converter of FIG. 1 delays driving any voltage until the voltage to be driven equals the voltage on pre-bias voltage present on the output node. Thus, the control loop continues to operate, but, ensures through the enable signal 602 (FIGS. 6A and 6B) supplied to NOG 621 that the FETs never actually turn on. When the reference voltage supplied through the ref_dac 301 is equal to the voltage on the output node, the control loop enables the output stage to supply the voltage. At that point, since the loop has been operating, the reference voltage value and the pulse-width state variable are as if the circuit has been driving according to its specified ramp the whole time. The control loop continues to drive to the specified ramp until the target voltage is reached.

### Sequencing

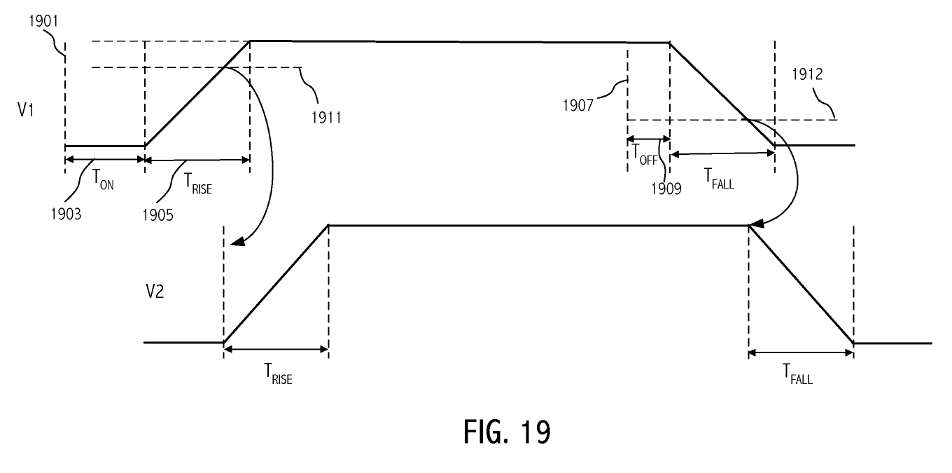

One aspect of the digital control for multiple outputs as described for embodiments herein is the ability to provide flexible sequencing control for the various voltage rails. Thus, sequencing control can be used to programmably specify for a particular rail, a variety of Boolean conditions to control output of the voltage rail. Various aspects of the voltage rail can be controlled. For example, a delay time (T_{ON}) from a Boolean event until the particular voltage rail begins to turn on can be specified. The rise time T_{RISE} can be specified. In addition the time between a particular Boolean event and the rail beginning to turn off (T_{OFF}) can be specified. The time it takes for the voltage rail to fall (T_{FALL}) can be specified. Referring to FIG. 19, exemplary waveforms for voltage rails V1, and V2 are illustrated. The V1 rail begins to turn on after a T_{ON} delay 1903 after a Boolean condition 1901 becomes true. That Boolean condition can be, e.g., an externally supplied analog voltage reaching a predetermined threshold level. That threshold level, along with the other Boolean conditions described herein, can be programmed through the communications interface. After the time delay, which can be zero, the V1 rail rises from 0 volts to the target voltage in a rise time 1905. In addition to specifying various aspects of turning on the voltage rail, various aspects of turning off the voltage rail can also be specified. For example, a delay 1909 (T_{OFF}) can be specified between an event 1907 and the beginning of the rail turning off. The rail goes from the target voltage to zero volts in the specified fall time T_{FALL}. The event 1907 can be the existence of one or more fault conditions, a command to turn-off, another voltage rail reaching a threshold value, a digital input, etc. Those events can be logically combined so the logic controlling the voltage rail will start T_{OFF} in response to the existence of any of the conditions or any logical combination of the conditions.

With respect to V2, in the particular example illustrated, T_{ON} is assumed to be zero. V2 begins to rise in time 1909 after the first voltage rail V1 reaches the threshold voltage 1911. While not shown in the particular example in FIG. 19, other conditions, e.g., the voltage level of V3, and/or the voltage level of an analog input signal, and/or other control or timing parameters can be combined with the threshold voltage of V1 to begin T_{RISE} of the V2 rail. Similarly, the fall of V2 can be predicated on a particular threshold voltage 1912 of V1 (or another rail). That threshold voltage condition of the V1 rail can be logically combined with voltage levels of other voltage rails and/or analog input signals and/or other control or timing parameters. The threshold sequential capability described herein may be particularly useful in situations where power is being shut down to ensure that power is shut down in an appropriate sequence to avoid damage to system components. In addition, power-up sequencing may benefit from the threshold sequential capability described herein.

While not shown in FIG. 3, the third voltage rail V3 can similarly be controlled based on one or more threshold voltages in combination with the conditions described above with relation to V1 and V2.

While the Boolean conditions as described above may be utilized to control sequencing of the rails, in an embodiment, one or more digital output signals may also be controlled by similar Boolean conditions. Thus, instead of turning on (or off) a power rail given the various conditions, a digital output signal may be controlled. Thus, various voltage, timing, and other conditions described above, including one or more digital inputs, may be considered in the Boolean logic that determines the digital output. Once the appropriate logical conditions have been satisfied, a programmable timer may be utilized to control how long to delay, if any, before asserting the actual, physical digital output, which itself may be configurable high/low. Once the trigger is de-asserted (one or more conditions are no longer true as appropriate to de-assert the trigger), a programmable timer may be utilized to determine how long, if at all, to delay before de-asserting the actual, physical digital output. The various conditions that determine that digital output may include, e.g., meeting the appropriate voltage thresholds on one or more rails and/or one more more analog inputs, timing parameters, one or more digital inputs, receipt of commands, fault conditions, etc.

This capability allows, e.g., receipt of a command to take an action on a power rail and have one or more digital signals assert before a rail actually responds. For example, such capability can be helpful in putting subsystems to sleep—e.g., assert a digital output signal to indicate that a rail is going to a low voltage state a period of time, e.g., 50 ms, before the rail itself changes.

As known to those of skill in the art, functionality described herein can be implemented in hardware, software, or a combination thereof. While circuits and physical structures are generally presumed for certain functions, it is well recognized that certain functionality may be embodied in programmable logic or implemented in software stored in computer-readable medium to operate on programmable devices such as microcontrollers. As used herein, a computer-readable medium includes various storage media such as flash memory, EEPROM, ROM, disk, tape, or other magnetic, optical, semiconductor, or electronic medium.

The description of the invention set forth herein is illustrative, and is not intended to limit the scope of the invention as set forth in the following claims. Variations and modifications of the embodiments disclosed herein may be made based on the description set forth herein, without departing from the scope and spirit of the invention as set forth in the following claims.

What is claimed is:

1. An apparatus comprising:
a current sensing circuit configured to generate a sensed current signal indicative of an average output current of a power converter circuit, the sensed current signal being at least partially based on a sample of a voltage signal on a first node of the power converter circuit, the first node being used to supply a current to an inductor of the power converter circuit.

2. The apparatus, as recited in claim 1, wherein the sample of the voltage signal is sampled at a point of the voltage signal corresponding to a point that a current through the inductor is approximately equal to the average output current of the power converter circuit.

3. The apparatus, as recited in claim 1, wherein the current sensing circuit comprises:
a delay-locked loop configured to generate a sample clock signal having a transition at a midpoint of a first phase of the voltage signal; and
a sampling circuit responsive to the sample clock signal to generate the sample of the voltage signal.

4. The apparatus, as recited in claim 3, wherein the first phase is the low phase of the voltage signal.

5. The apparatus, as recited in claim 1, further comprising:
a first circuit portion of the power converter circuit, the first circuit portion including a high-side circuit coupled to the first node and a low-side circuit coupled to the first node, the high-side circuit and the low-side circuit being configured to generate the voltage signal on the first node, wherein the voltage signal has a first phase and a second phase at least partially based on a first pulse-width of a pulse of a high-side control signal coupled to the high-side circuit and a second pulse-width of a pulse of a low-side control signal coupled to the low-side circuit.

6. The apparatus, as recited in claim 5, further comprising:
a control circuit configured to modulate the first and second pulse-width of the first signal and the second signal, respectively; and
a non-overlapping signal generator configured to generate the high-side control signal and the low-side control signal, wherein the pulse of the high-side control signal and the pulse of the low-side control signal are non-overlapping.

7. The apparatus, as recited in claim 5, further comprising:
a second circuit portion of the power converter circuit comprising:
the inductor coupled between the first node and a second node; and
a capacitor coupled between the second node and a first power supply node,
wherein the second node is configured to provide the average output current.

8. The apparatus, as recited in claim 5, wherein the current sensing circuit includes a version of the low-side circuit, the current sensing circuit being configured to generate the sensed current signal at least partially based on a first current and a sample of a calibration voltage signal generated at least partially based on a response of the version of the low-side circuit to the first current.

9. The apparatus, as recited in claim 8, wherein the calibration voltage signal and the voltage signal are sampled by the same circuit to generate the sample of the calibration voltage signal and the sample of the voltage signal.

10. The apparatus, as recited in claim 8, wherein the current sensing circuit comprises a digital circuit configured to generate at least one of a calibrated version of the sample of the voltage signal on the first node and a calibrated version of the sample of the calibration voltage signal and to generate the sensed current signal at least partially based thereon.

11. The apparatus, as recited in claim 10, wherein the digital circuit is configured to determine an input current of the voltage converter circuit at least partially based on the sensed current signal and on a duty cycle of a pulse-width modulated control signal used to generate the voltage signal on the first node.

12. The apparatus, as recited in claim 11, wherein the input current is at least partially based on a selectable duty cycle offset value.

13. The apparatus, as recited in claim 1, wherein the power converter circuit is a buck converter circuit.

14. A method comprising:
determining an average output current of a power converter circuit at least partially based on a sample of a voltage signal on a first node of the power converter circuit, the first node being configured to supply a current to an inductor of the power converter circuit.

15. The method, as recited in claim 14, further comprising:
sampling the voltage signal at a point when the current supplied to the inductor by the first node is approximately equal to the average output current of the power converter circuit.

16. The method, as recited in claim 15, further comprising:
generating a sample clock signal having a transition at a midpoint of a first phase of the voltage signal, the sample clock signal being used to sample the voltage signal.

17. The method, as recited in claim 14, further comprising:
sensing a calibration voltage signal at least partially based on a first current and a response of a version of a portion of the power converter circuit to the first current and generating a sample of the calibration voltage signal based thereon.

18. The method, as recited in claim 17, wherein the sensing comprises generating the sensed current signal at least partially based on a calibrated version of the sample of the voltage signal on the first node and a calibrated version of the sample of the calibration voltage signal.

19. The method, as recited in claim 18, further comprising:
determining an input current of the voltage converter circuit at least partially based on the sensed current signal and on a duty cycle of a pulse-width modulated control signal used to generate the voltage signal on the first node.

20. The method, as recited in claim 19, wherein the input current is at least partially based on a selectable duty cycle offset value.

21. An apparatus comprising:
a power converter circuit portion; and
means for determining a current signal indicative of an output current of a power converter circuit including the power converter circuit portion at least partially based on a sample of a voltage signal on a first node of the power converter circuit portion, the first node supplying a current to a second power converter circuit portion and generating a sensed current signal at least partially based thereon.

22. The apparatus, as recited in claim 21, wherein the means for determining comprises:
means for generating a sample clock signal having a transition at a midpoint of a first phase of the voltage signal; and
means for sampling the voltage signal and generating the sample of the voltage signal at least partially based on the sample clock signal.

23. The apparatus, as recited in claim 21, wherein the means for determining comprises a means for generating a calibration voltage signal.

24. The apparatus, as recited in claim 21, further comprising:
means for determining an input current the voltage converter circuit at least partially based on the sensed current signal and on a duty cycle of a pulse-width modulated control signal used to generate the voltage signal on the first node.
